(19) United States
(12) Patent Application Publication
(10) Pub. No.: US 2013/0037308 A1
(43) Pub. Date: Feb. 14, 2013

(54) REINFORCED GLASS CELL AND METHOD FOR FABRICATING THE SAME AND COVER GLASS HAVING THE REINFORCED GLASS CELL

(71) Applicants: Po-Hsien Wang, Taichung City (TW); Hsuan-Yang Chen, Hualien County (TW); Chi-Yu Chan, Taichung City (TW); Jeng-Jye Hung, Taichung City (TW)

(72) Inventors: Po-Hsien Wang, Taichung City (TW); Hsuan-Yang Chen, Hualien County (TW); Chi-Yu Chan, Taichung City (TW); Jeng-Jye Hung, Taichung City (TW)

(73) Assignees: WINTEK CORPORATION, Taichung City (TW); DONGGUAN MASSTOP LIQUID CRYSTAL DISPLAY CO., LTD., Guangdong Province (CN)

(21) Appl. No.: 13/571,363

(22) Filed: Aug. 10, 2012

(30) Foreign Application Priority Data
Aug. 12, 2011 (TW) 100128936

(51) Int. Cl. C03C 21/00; C03C 15/00; H05K 1/02; B32B 17/00

(52) U.S. Cl. 174/250; 65/30.14; 428/194

(57) ABSTRACT

A method of fabricating a reinforced glass cell including the following steps is provided. First, a mother glass having a plurality of glass cell predetermined regions is provided. A portion of the mother glass disposed on the outer edge of each glass cell predetermined region is removed, so as to form at least one through trench and at least one linking bridge. Herein, the through trench exposes the periphery section of each glass cell predetermined region, and the glass cell predetermined regions are formed as an entire patterned mother glass by the linking bridges. A reinforcing process is performed to the entire patterned mother glass, so that the exposed periphery sections of the glass cell predetermined regions are formed into reinforced sections. The linking bridges are removed so as to separate the glass cell predetermined regions having the reinforced sections to form a plurality of reinforced glass cells.

### CROSS-REFERENCE TO RELATED APPLICATION

This application claims the priority benefit of Taiwan application serial no. 100128936, filed on Aug. 12, 2011. The entirety of the above-mentioned patent application is hereby incorporated by reference herein and made a part of this specification.

### BACKGROUND OF THE INVENTION

1. Field of the Invention

The invention relates to a glass cell and a method of fabricating the same and a cover glass. More particularly, the invention relates to a reinforced glass cell and a method of fabricating the same and a cover glass having the reinforced glass cell.

2. Description of Related Art

With their widespread applications, display panels are applied in various portable electronic products such as personal digital assistants (PDAs), mobile phones, tablet personal computers (PCs). Since most of these portable electronic products have built-in touch sensing functions and are easily dropped when carrying or using, the glass substrates of the display panels thereof need reinforced hardness particularly.

In conventional technology, a method of fabricating a reinforced glass includes the following. Firstly, a mother glass is diced into small pieces of glass cells. An edge routing process is then performed to these pieces of glass cells respectively. Thereafter, a reinforcing process is performed to these pieces of glass cells respectively to form reinforced glasses. A subsequent process (e.g. a touch panel process, a black decorative frame process, or so on) is performed to the reinforced glasses. However, this method includes complicated processes, is labor and time consuming, and has higher cost.

Another method of fabricating a reinforced glass is shown below. Firstly, a reinforcing process is performed to a mother glass to form a reinforced mother glass. A subsequent process (e.g. a touch panel process, a black decorative frame process, or so on) is performed to the reinforced mother glass. The reinforced mother glass is then diced through a dicing process to form a plurality of reinforced glasses. Currently, in the process of dicing the reinforced mother glass, bursting points are generated in the reinforced mother glass during the dicing process since the reinforced mother glass has higher hardness. As a consequence, the reinforced mother glass breaks, thereby leading to lower yield rate of reinforced glasses. In addition, small pieces of glass cells fabricated from this fabrication are adopted as final products directly. Since the new sections diced from the dicing tracks of the small pieces of glass cells are not exposed in the reinforcing process and thus not reinforced. Accordingly, these small glass cells then have tiny cracks generated on the edges thereof in the subsequent processes such as edge routing, chamfering process, and the like, thereby decreasing the hardness of glass enormously and resulting in breakage of the final products easily. Therefore, researchers now focus on developing a method of fabricating a reinforced glass with high yield rate and low cost.

### SUMMARY OF THE INVENTION

The invention is directed to a method of fabricating a reinforced glass cell. The method is capable of enhancing the production rate and yield rate of reinforced glass and also reducing fabrication cost effectively.

The invention is directed to a reinforced glass cell having high mass productivity, high hardness, high yield rate, and low fabrication cost.

The invention is directed to a method of fabricating a reinforced glass cell, the method includes the following steps. A mother glass having a plurality of glass cell predetermined regions thereon is provided. A portion of the mother glass on an outer edge of each of the glass cell predetermined regions is removed to form at least one through trench and at least one linking bridge on an edge of each glass cell predetermined region, wherein the through trench exposes a periphery section of each of the glass cell predetermined regions, and the glass cell predetermined regions constitute an entire patterned mother glass through the linking bridges. A reinforcing process is performed to the entire patterned mother glass for the periphery sections exposed on the glass cell predetermined regions to form a plurality of reinforced sections. The linking bridges are removed to separate the glass cell predetermined regions having the reinforced sections so as to form a plurality of reinforced glass cells.

The invention is further directed to a reinforced glass cell. The reinforced glass cell includes a glass substrate having an upper surface, a lower surface, and a periphery surrounding side surface. The periphery surrounding side surface connects the upper surface and the lower surface. The periphery surrounding side surface has at least one reinforced section and at least one unreinforced section, where an area of the reinforced section is larger than that of the unreinforced section.

The invention is further directed to a cover glass including a reinforced glass cell, a touch sensing electrode structure, and a decoration layer. The reinforced glass cell has an upper surface, a lower surface, and a periphery surrounding side surface. The periphery surrounding side surface connects the upper surface and the lower surface. The periphery surrounding side surface has at least one reinforced section and at least one unreinforced section, where an area of the reinforced section is larger than that of the unreinforced section. The touch sensing electrode structure is disposed on at least one surface of the reinforced glass cell. The decoration layer is disposed on the reinforced glass cell.

In light of the foregoing, in the method of fabricating the reinforced substrate in the invention, the mother glass is patterned partially, so that an edge of each of the glass cell predetermined regions forms at least one through trench exposing the periphery section thereof. Moreover, the glass cell predetermined regions constitute an entire patterned mother glass through the linking bridges. A reinforcing process is performed to the entire patterned mother glass so as to reinforce two opposite surfaces and the periphery section of each of the glass cell predetermined regions simultaneously, thereby reducing the fabrication cost of the reinforced glass cell effectively. In addition, since the glass cell of the invention has reinforced most of the periphery surrounding side surface thereof before the separation and the area of the reinforced section is larger than that of the unreinforced section in the periphery surrounding side surface, the hardness and the production yield rate of the reinforced glass cell can be enhanced effectively.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIGS. 1A to 1F are schematic top views illustrating a flowchart of fabricating a reinforced glass cell according to an embodiment of the invention.

FIGS. 2A to 2F are schematic cross-sectional views taken along line AA in FIGS. 1A to 1F respectively to illustrate the flowchart of fabricating the reinforced glass cell.

FIGS. 3A and 3B are respectively layout disposition diagrams of a glass cell predetermined region in a method of fabricating a reinforced glass cell in the invention.

FIG. 4A is a three-dimensional diagram of a reinforced glass cell in the invention.

FIG. 4B is a partial section view taken along path BB′ in a periphery surrounding side surface in FIG. 4A.

FIGS. 4C to 4E are respectively potassium ion content trend charts measured corresponding to a plurality of measuring positions in FIG. 4B.

FIGS. 5A to 5D respectively illustrate a cover glass adopting the reinforced glass cell aforementioned as a glass substrate.

### DESCRIPTION OF EMBODIMENTS

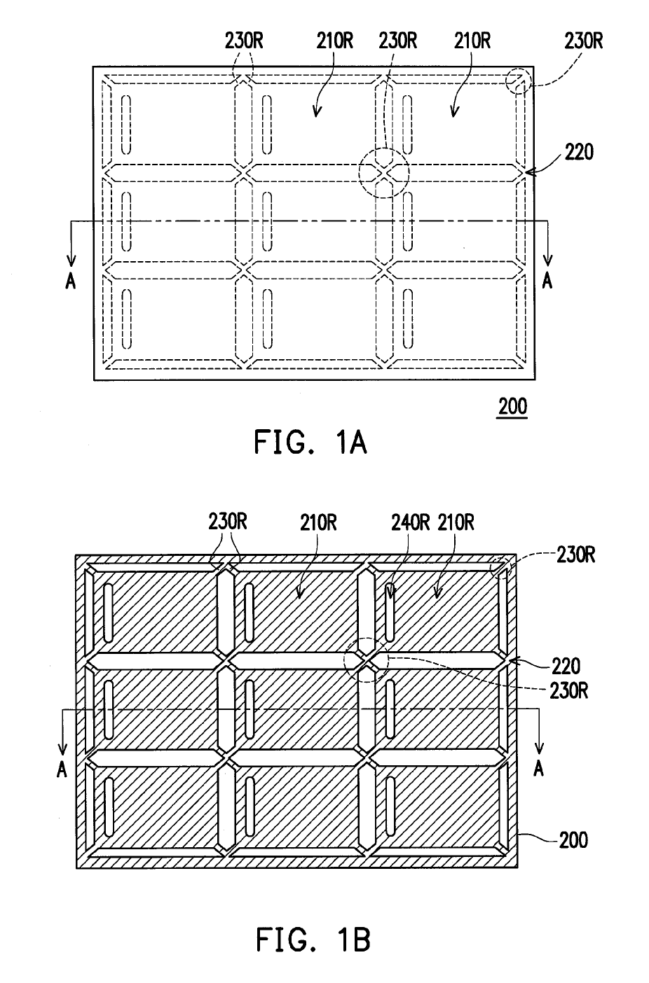

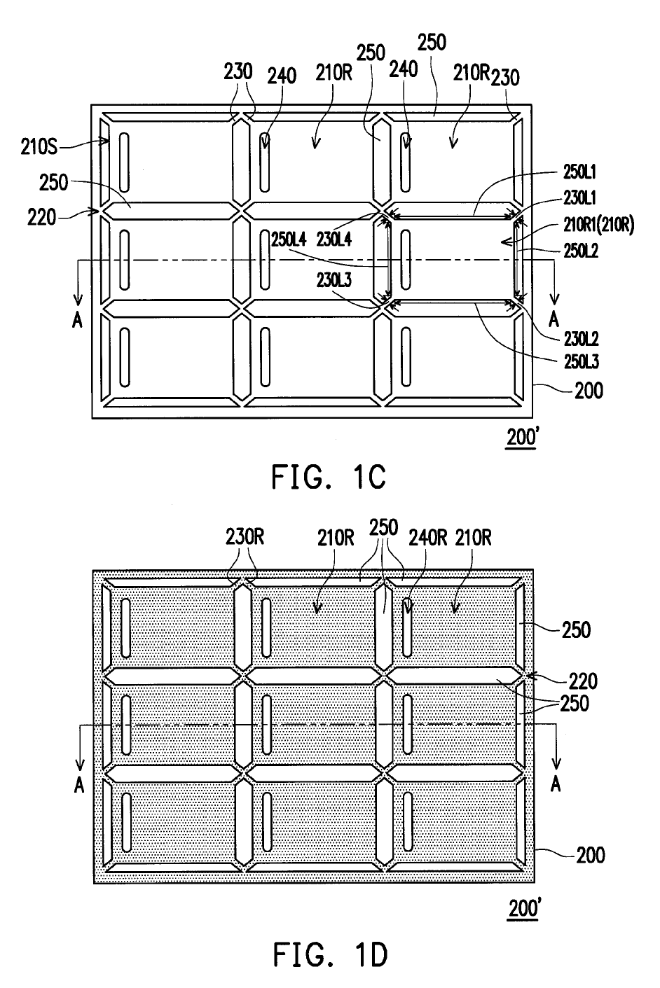

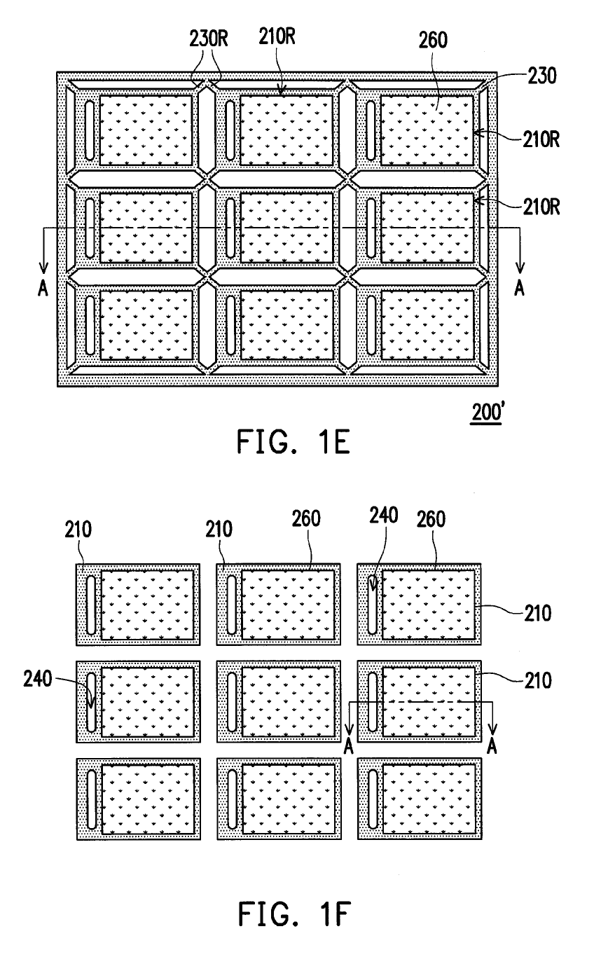

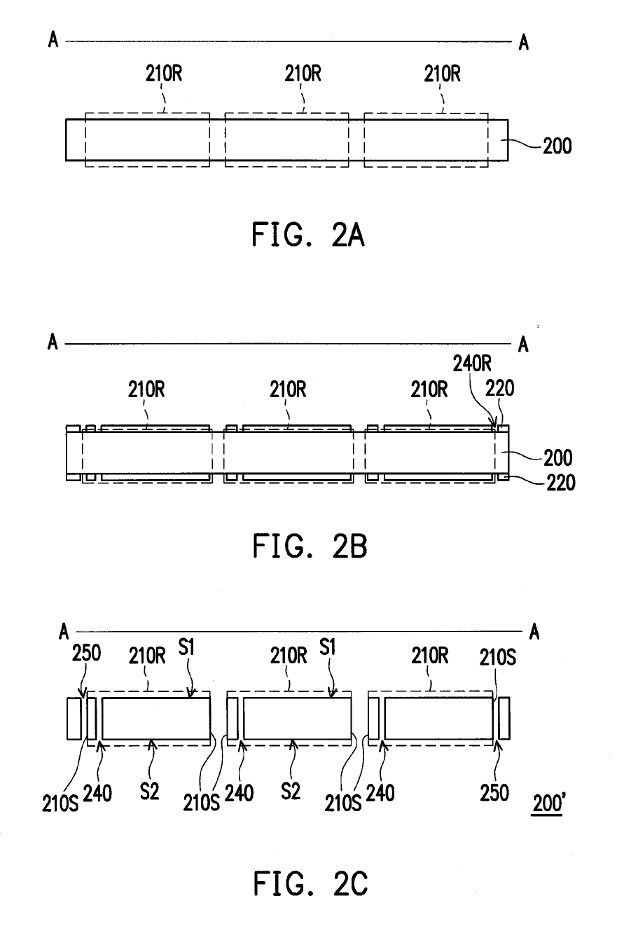

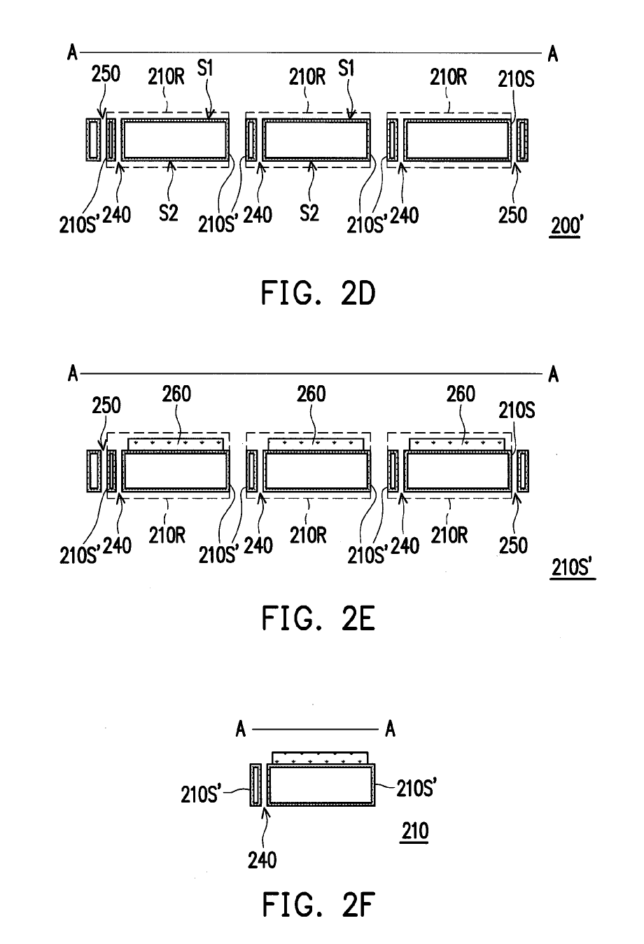

FIGS. 1A to 1F are schematic top views illustrating a flowchart of fabricating a reinforced glass cell according to an embodiment of the invention. FIGS. 2A to 2F are schematic cross-sectional views taken along line AA in FIGS. 1A to 1F respectively to illustrate the flowchart of the method of fabricating the reinforced glass cell. Referring to FIGS. 1A and 2A, firstly, a mother glass 200 having a plurality of glass cell predetermined regions 210R is provided. In the present embodiment, nine glass cell predetermined regions 210R in a 3×3 matrix are schemed on the mother glass 200. However, the invention is not limited thereto, and the size and number of the glass cell predetermined regions 210R on the mother glass 200 can be adjusted suitably according to the disposition of active regions on the mother glass 200, the process window of the production line, and the product demand. In addition, a material of the mother glass 200 in the present embodiment is, for example, a soda-lime glass; however, the invention is not limited thereto. In other embodiments, the mother glass 200 can also be fabricated using an alkali free glass, a boron glass, an aluminosilicate glass, a lithium aluminum silicate glass, or other suitable material.

Next, before a portion of the mother glass 200 is removed from an outer edge of each of the glass cell predetermined regions 210R using a patterning process (as depicted in FIGS. 1C and 2C subsequently), a patterned protection film 220 can be adhered on the glass cell predetermined regions 210R on the mother glass 200 and a plurality of predetermined formation regions of the linking bridges according to fabrication demands (as shown in FIGS. 1B and 2B).

In other words, the patterned protection film 220 is covered on regions to be reserved such as the glass cell predetermined regions 210R and a plurality of predetermined formation regions 230R of the linking bridges 230 (shown in FIGS. 1C and 2C). Consequently, the mother glass 200 on the covered regions is protected from being removed during a subsequent removing process for removing a portion of the mother glass 200. In the present embodiment, the patterned protection film 200 not only exposes most of the outer edge of each of the glass cell predetermined regions, but also exposes a predetermined formation region 240R of a through hole 240 (shown in FIGS. 1C and 2C) of each of the glass cell predetermined regions 210R.

In the present embodiment, a material of the patterned protection film 220 is a material protecting from etching solutions such as hydrofluoric acid and so on. A method of forming the patterned protection film 220 includes the following, for example. A patterning process is performed to an entire protection film. The patterning process includes a printing process, an adhering process, a laser process, a knife wheel process, a photolithography process, an etching process, or a combination thereof. For example, when the patterned protection film 220 is fabricated with a photo-resist material, the patterning process can be a photolithography process such as exposure, development, and so on, or an etching process; when the patterned protection film 220 is fabricated with a removable gel, the patterning process can be a printing process such as a screen printing process.

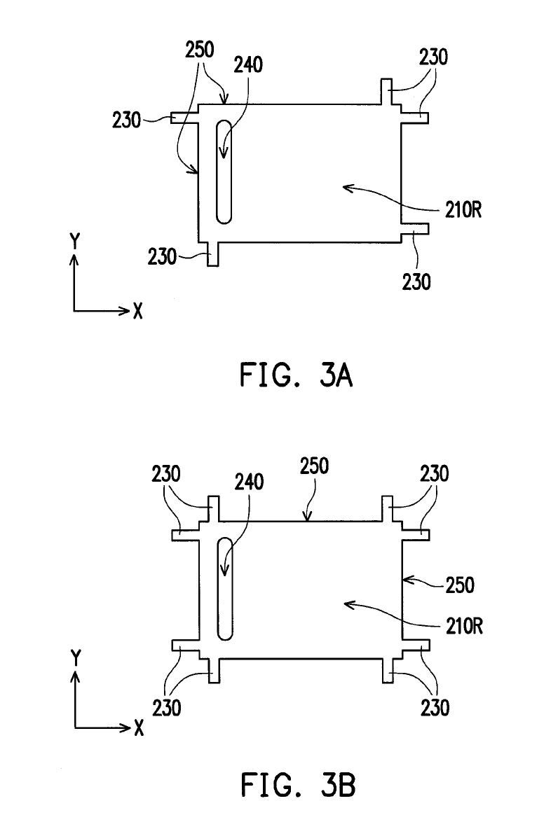

Thereafter, referring to FIGS. 1C and 2C, a portion of the mother glass 200 on the outer edge of each of the glass cell predetermined regions 210R is removed to form at least one through trench 250 and at least one linking bridge 230 on an edge of each glass cell predetermined region 210R. The through trench 250 exposes a periphery section 2105 of each of the glass cell predetermined regions 210R and the glass cell predetermined regions 210R constitute an entire patterned mother glass 200′ through linking by the linking bridges 230. In the present embodiment, the linking bridges 230 are located at a corner of each of the glass cell predetermined regions 210R and are connected to other glass cell predetermined regions 210R in radiant or other shapes. The details are further described in FIGS. 3A and 3B below.

Specifically, when removing a portion of the mother glass 200 on the outer edge of each of the glass cell predetermined regions 210R, the mother glass is generally removed around the periphery of each glass cell predetermined region 210R (e.g. four sides) in thickness direction until the mother glass 200 is penetrated through. Therefore, the depth of the through trenches 250 formed in this step substantially equals to the thickness of the mother glass 200, and the length of the through trenches 250 is generally less than the perimeter occupied by each of the glass cell predetermined regions 210R.

In other words, in the mother glass 200 located in each of the glass cell predetermined regions 210R, since the through trench 250 connects an upper surface S1 and a lower surface S2 of each glass cell predetermined region 210R, and the length of the through trench 250 substantially surrounds the perimeter occupied by the upper surface S1 of the glass cell predetermined region 210R, a large portion of the periphery section 210S is exposed by the through trench 250 in a periphery surrounding side surface of each glass cell predetermined region 210R. Here, only a small portion of the mother glass 200 is adopted as the linking bridges 230 to support each of the glass cell predetermined regions 210R on the patterned mother glass 200′. Accordingly, when performing a subsequent reinforcing process, the entire patterned mother glass 200′ is used as a processing unit to enhance the mass production rate and the yield rate effectively.

As illustrated in FIG. 1C, take the perimeter of each glass cell predetermined region 210R as the standard, the total length occupied by the through trenches 250 in perimeter is longer than a total length occupied by the linking bridges 230 in perimeter. For example, in the glass cell predetermined region 210R shown in the drawing, the total length of the through trenches 250 is a sum of lengths 250L1 to 250L4 of the through trenches 250, for instance, and the total length of the linking bridges 230 is a sum of lengths 230L1 to 230L4 of the linking bridges 230, for instance. That is, observed from the upper surface S1 of each of the glass cell predetermined regions 210R, a total sum of the length of the through trench 250 and the length of the linking bridge 230 substantially equals to a perimeter of the upper surface S1 in each of the glass cell predetermined regions 210R. In the present embodiment, a method of removing a portion of the glass from the outer edge of each glass cell predetermined region 210R includes a physical borehole process such as a water jet process, an etching process adopting a chemical etching solution, or a laser process. The removing method can be incorporated with the protection film aforementioned depending on the situation.

It should be noted that as depicted in FIGS. 2B and 2C, in the present embodiment after a portion of the mother glass 200 is removed to form the patterned mother glass 200′, the patterning protection film 220 is removed to remove the protection film on the upper surface S1 and the lower surface S2 of the patterned mother glass 200′.

Also, as shown in FIGS. 1C and 2C, in the present embodiment, the method of fabricating the reinforced glass cell further includes routing the periphery section 210S of each glass cell predetermined region 210R after the through trench 250 exposing each glass cell periphery section 2105 is formed. Specifically, in this step, processes such as routing, chamfering, and so on can be performed to the periphery sections 210S exposed by the through trenches 250 so as to smoothen the periphery sections 210S on the edge of each of the glass cell predetermined regions 210R.

Then, referring to FIGS. 1D and 2D, a reinforcing process is performed to the entire patterned mother glass 200′, so that the periphery sections 210S exposed on the glass cell predetermined regions 210R form a plurality of reinforced sections 210S′, thereby enhancing the overall glass hardness of the glass cell product. In the present embodiment, the reinforcing process includes a chemical reinforcing process. For example, this chemical reinforcing process includes soaking the entire patterned mother glass 200′ in a chemical reinforcing solution. The chemical reinforcing solution has alkaline metal ions with atomic radius larger than that of sodium; that is, the chemical reinforcing process can be an ion exchange process. Particularly, when the mother glass 200 is fabricated with the soda-lime glass, the mother glass 200 can be soaked in a potassium nitrate solution for replacing the sodium ions having smaller ion radius (sodium ion having smaller atomic radius) with potassium ions having larger ion radius (potassium ions having larger atomic radius) in the mother glass 200 made with the soda-lime glass. After being embedded into the mother glass of the soda-lime glass, the potassium ions having larger ion radius compress each other on a surface of the mother glass 200 fabricated with the soda-lime glass so as to generate compression stress on the surface, thereby reinforcing the mother glass 200 made of the soda-lime glass. However, the invention is not limited thereto, in other embodiment, the reinforcing process can also use other chemical reinforcing solutions or be other suitable methods.

Especially in the reinforcing process of the present embodiment, the periphery surrounding side surface of each of the glass cell predetermined regions 210R corresponding to the linking bridge 230 is not exposed, so that the surface is not affected by the chemical reinforcing process. Since the alkaline metal ions with atomic radius larger than that of sodium can be diffused from the hollow through trenches 250 and the linking bridges 230 are much smaller than the through trenches 250, the periphery surrounding side surface of each glass cell predetermined region 210R corresponding to the linking bridge 230 is still partially reinforced. The reinforced coverage thereof ranges from 0 μm to 200 μm from the edge of the linking bridges 230. In the present embodiment, after the reinforcing process, the depth of layer (DOL) can range from greater than 0 μm to 150 μm. Furthermore, the stress on the glass surface ranges from 100 MPa to 900 MPA, for example, after the reinforcement.

Referring to FIGS. 1E and 2E, it should be illustrated that in practice, in the method of fabricating the reinforced glass cell of the present embodiment, a device layer 260 can be further formed on an active region of the patterned mother glass depending on the type of the glass cell final product generated after the reinforced section 210S′ is formed in each glass cell predetermined region 210R of the patterned mother glass. For instance, when the glass cell final product is adopted as a substrate of a touch panel, the device layer 260 can be a touch sensing device, for example, a sensing circuit, a conductive circuit, a black matrix layer, a thin film transistor, or a combination thereof; when the glass cell final product is applied as a transparent cover glass, the device layer 260 can be an anti-reflection layer, an anti-smudge layer, or a light-shielding layer.

Afterwards, referring to FIGS. 1F and 2F, the linking bridges 230 on the patterned mother glass 200′ are removed to separate the glass cell predetermined regions 210R having the reinforced sections 210S′ so as to form a plurality of reinforced glass cells 210. It should be noted that since the glass cells undergo a single reinforcing process as an entire patterned mother glass 200′ before the separation, most of the surface and the section of each glass cell are reinforced simultaneously in this one time reinforcing process. As a result, the fabrication cost can be reduced effectively and the overall mass productivity can be enhanced.

In the following, the layouts of various types of linking bridges connecting to adjacent glass cell predetermined regions in the mother glass are illustrated along with FIGS. 3A and 3B.

FIGS. 3A and 3B are respectively layout disposition diagrams of a glass cell predetermined region in a method of fabricating a reinforced glass cell in the invention. Here, 5 (as shown in FIG. 3A) or 8 (as shown in FIG. 3B) linking bridges 230 extending outward can be disposed along an XY direction in the corner of the glass cell predetermined region 210R.

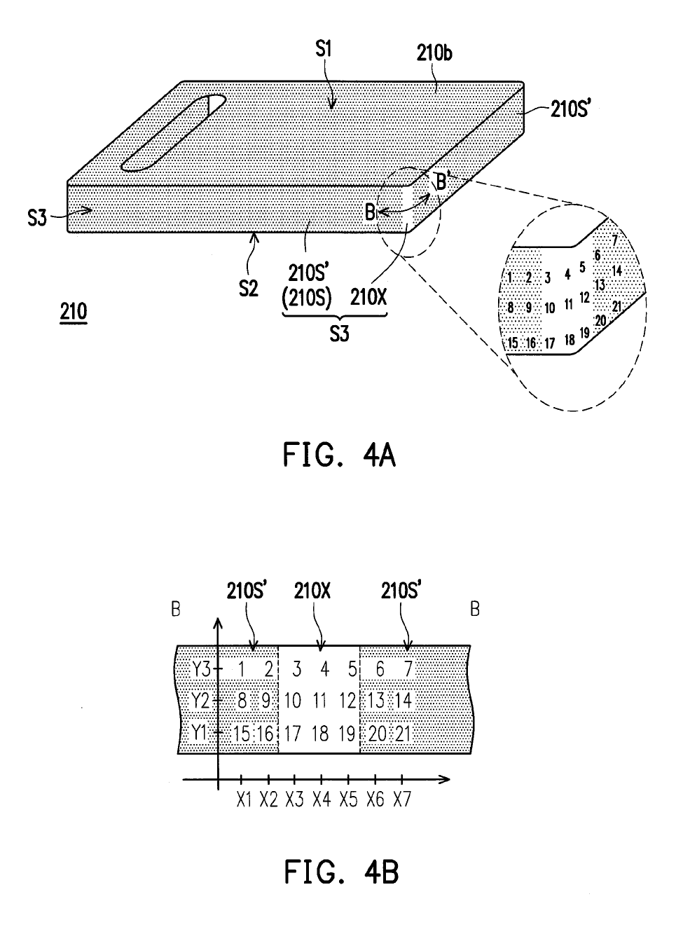

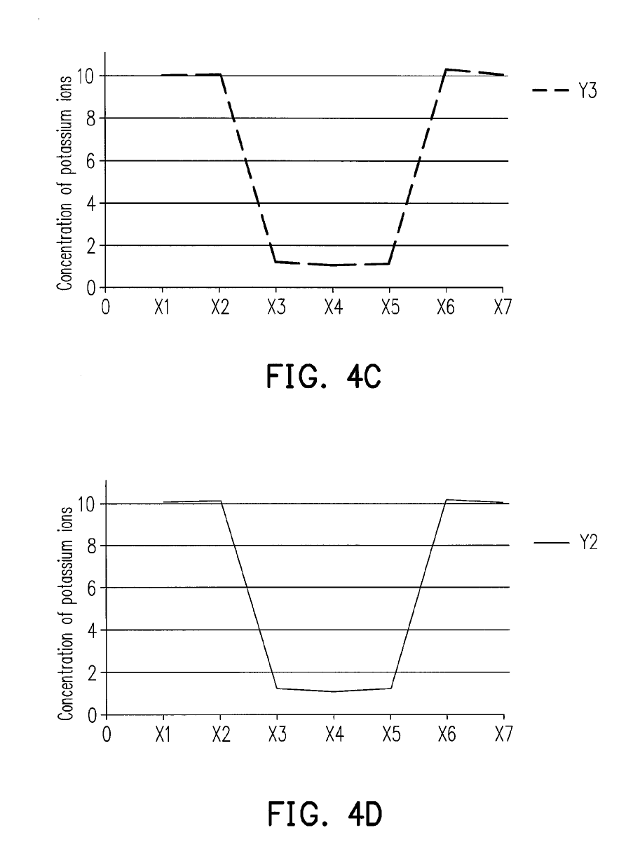

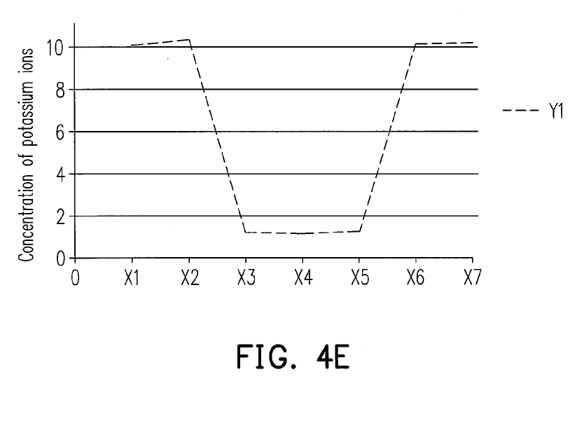

To further describe the structure of the reinforced glass cell 210 in the invention, the reinforced glass cell 210 is used as an example and illustrated with the accompanying drawings FIGS. 4A and 4B.

FIG. 4A is a three-dimensional diagram of a reinforced glass cell in the invention. As depicted in FIG. 4, the reinforced glass cell 210 includes a glass substrate 210b having an upper surface S1, a lower surface S2, and a periphery surrounding side surface S3. The periphery surrounding side surface S3 connects the upper surface S1 and the lower surface S2. The periphery surrounding side surface S3 has at least one reinforced section 210S′ and at least one unreinforced section 210X. Accordingly, the reinforced section 210S′ is the periphery section 210 exposed by the through trench 250 in each of the glass cell predetermined regions 210R (displayed in FIGS. 1C and 2C), and the unreinforced sections 210X are regions corresponding to the linking bridges 230. As illustrated in FIG. 4A, since the total length occupied by the through trenches 250 in the perimeter of each of the glass cell predetermined regions 210R is much longer than the total length occupied by the linking bridges 230 in perimeter, the total area of the reinforced sections 210S′ is much larger than that of the unreinforced sections 210X on the periphery surrounding side surface S3 of the glass substrate 210b.

More specifically, the reinforced sections 210S′ of the reinforced glass cell 210 in the present embodiment have alkaline metal ions with atomic radius larger than that of sodium, for example, potassium ions, and the concentration of the alkaline metal ions in the reinforced sections 210S′ is higher than the concentration of the alkaline metal ions in the unreinforced sections 210X.

FIG. 4B is a schematic diagram showing measuring points in a partial enlarged diagram expanded along path BB′ in a periphery surrounding side surface in FIG. 4A. The potassium ion content on each point in FIG. 4B is measured and the measuring results are illustrated in FIGS. 4C to 4E. Here, as depicted in FIGS. 4A and 4B, a plurality of measuring positions 1 to 21 are divided to correspond to different Y axes Y1 to Y3 and different X axes X1 to X7 on XY coordinate axes. The potassium ion concentration on different XY coordinates is measured individually. FIGS. 4C, 4D, and 4E are potassium ion concentration curves of curve Y3, curve Y2, and curve Y1 in FIGS. 4A and 4B respectively. FIG. 4C shows the potassium ion concentration measured on measuring points 1-7 on the same Y3 coordinate but different X coordinates X1-X7; FIG. 4D shows the potassium ion concentration measured on measuring points 8-14 on the same Y2 coordinate but different X coordinates X1-X7; FIG. 4E shows the potassium ion concentration measured on measuring points 15-21 on the same Y1 coordinate but different X coordinates X1-X7.

Shown in FIGS. 4C to 4E, the reinforced sections 210S′ and the unreinforced sections 210X are present simultaneously in the reinforced glass cell 210, and the potassium ion concentration of the reinforced section 210S′ is higher than the potassium ion concentration of the unreinforced section 210X.

Table 2 further displays a result of comparing the bending strength of the reinforced glass cell 210 in the invention to that of conventional reinforced glass in different applications.

TABLE 2

| Application | Method of fabricating the | Average |
|---|---|---|
| Scope | reinforced glass cell 210 | Strength (N) |
| Touch panel | Reinforced glass fabricated using | 140.8 |
| | conventional method [1] | |
| | Reinforced glass cell 210 of the invention | 470.3 |
| Transparent | Reinforced glass fabricated using | 457.2 |
| cover glass | conventional method | |
| | Reinforced glass cell 210 of the invention | 470.3 |

[1] Reinforced glass fabricated using conventional method is the reinforced glass fabricated by reinforcing the mother glass first and then dicing the mother glass into small pieces of reinforced glasses (dicing sections unreinforced).

As illustrated in Table 2, comparing to conventional method of fabricating reinforced glass, the reinforced glass cell 210 of the invention has superior glass hardness when adopted as a substrate of a touch panel or a transparent cover glass.

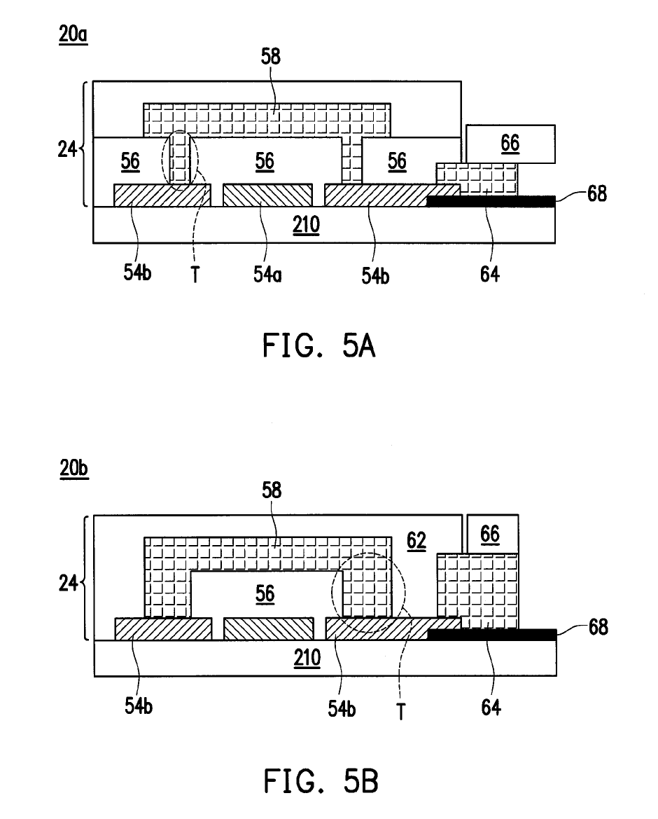

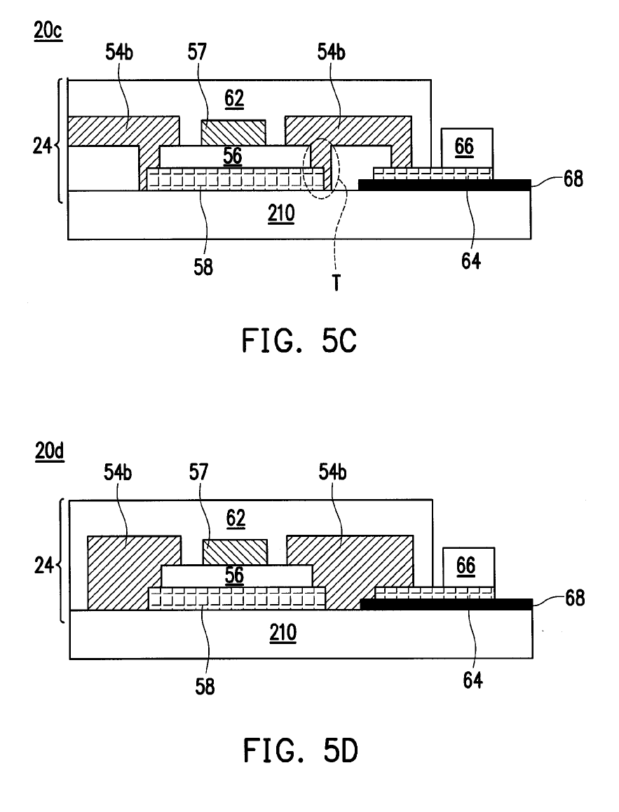

FIGS. 5A to 5D respectively illustrate a cover glass adopting the reinforced glass cell aforementioned as a glass substrate. As depicted in FIG. 5A, a cover glass structure 20a includes a glass substrate constituted by the aforementioned reinforced glass cell 210 and a touch sensing electrode structure 24 formed on the reinforced glass cell 210. Herein, the touch sensing electrode structure 24 is deemed as the device layer 260. The reinforced glass cell 210 undergoes the reinforcing and then dicing process. In the present embodiment, the touch sensing electrode structure 24 has a bridge via electrode structure. As shown in FIG. 5A, a plurality of first transparent electrodes 54a equidistantly distributed and parallel to one another along an X axis direction and a plurality of second transparent electrodes 54b equidistantly distributed and parallel to one another along a Y axis direction are disposed on a surface of the reinforced glass cell 210. An insulation layer 56 covers the first transparent electrodes 54a and the second transparent electrodes 54b, and is disposed with a plurality of vias T to expose a portion of a plurality of second transparent electrode regions 540b. A second connection line 58 is electrically connected to different second transparent electrodes 54b respectively through the via T. A protection layer 62 covers the first transparent electrodes 54a, the second transparent electrodes 54b, the insulation layer 56, and the second connection line 58. The touch sensing electrode structure 24 is disposed between the protection layer 62 and the reinforced glass cell 210. The touch sensing electrode structure 24 is electrically connected to a flexible circuit board 66 or a control IC (not shown) through a metal wire 64. A decoration layer 68 is disposed on the reinforced glass cell 210 to shield the metal wire 64. For instance, the decoration layer 68 can be disposed in the periphery of the reinforced glass cell 210 and surrounds the touch sensing electrode structure of the cover glass or the visible region of the touch sensing device. The decoration layer 68 is constituted by at least one of diamond-like carbon, ceramic, ink, or photo-resist material, for example.

As illustrated in FIG. 5B, a cover glass structure 20b includes a reinforced glass cell 210 and a touch sensing electrode structure 24 formed on the reinforced glass cell 210. The reinforced glass cell 210 undergoes the reinforcing and then dicing process. In the present embodiment, the touch sensing electrode structure 24 has a bridge island electrode structure. The protection layer 62 is disposed on a surface of the touch sensing electrode structure 24 different from the reinforced glass cell 210 and extends downward, thereby reducing the range of the insulation layer 56. The via T is disposed between the protection layer 62 and the insulation layer 56.

As shown in FIG. 5C, a cover glass structure 20c includes a reinforced glass cell 210 and a touch sensing electrode structure 24 formed on the reinforced glass cell 210. The reinforced glass cell 210 undergoes the reinforcing and then dicing process. In the present embodiment, the touch sensing electrode structure 24 has an underground via electrode structure. Herein, the adjacent first transparent electrodes 54a (not shown) are serially connected through a first connection line 57, and the adjacent second transparent electrodes 54b are serially connected through a second connection line 58. The first connection line 57 or the second transparent electrodes 54b can be formed above the insulation layer 56. The second connection line 58 is formed below the insulation layer 56, where a plurality of vias T is disposed in the insulation layer 56.

As shown in FIG. 5D, a cover glass structure 20d includes a reinforced glass cell 210 and a touch sensing electrode structure 24 formed on the reinforced glass cell 210. The reinforced glass cell 210 undergoes the reinforcing and then dicing process. In the present embodiment, the touch sensing electrode structure 24 has an underground via electrode structure. Herein, the adjacent first transparent electrodes 54a (not shown) are serially connected through a first connection line 57, and the adjacent second transparent electrodes 54b are serially connected through a second connection line 58. The first connection line 57 can be formed above the insulation layer 56. The second connection line 58 is formed below the insulation layer 56. Moreover, any one of the above mentioned cover glass structure mention 20a to 20d can further includes at least one functional film (not shown) disposed on at least one side of the reinforced glass cell. The functional film can be at least one of a polaroid, a filter glass, an anti-glare filter, an anti-reflection film, a polyethylene terephthalate (PET) material, or a hard coating material, for example.

In summary, in the method of fabricating the reinforced substrate in the invention, the mother glass is patterned first, so that an edge of each of the glass cell predetermined regions forms at least one through trench exposing the periphery section thereof, and also forms at least one linking bridge for connecting a plurality of glass cell predetermined regions to constitute an entire patterned mother glass. Moreover, a reinforcing process is performed to the entire patterned mother glass so as to reinforce two opposite surfaces and the periphery section of each of the glass cell predetermined regions, thereby reducing the fabrication cost of the reinforced glass cell effectively. In addition, since the glass cell of the invention has reinforced most of the periphery surrounding side surface thereof before the separation and the area of the reinforced section is larger than that of the unreinforced section in the periphery surrounding side surface, the hardness and the production yield rate of the reinforced glass cell can be enhanced effectively.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A method of fabricating a reinforced glass cell, the method comprising:
providing a mother glass having a plurality of glass cell predetermined regions thereon;
removing a portion of the mother glass on an outer edge of each of the glass cell predetermined regions to form at least one through trench and at least one linking bridge on an edge of each glass cell predetermined region, wherein the through trench exposes a periphery section of each of the glass cell predetermined regions and the glass cell predetermined regions constitute an entire patterned mother glass through the linking bridges;
performing a reinforcing process to the entire patterned mother glass for the periphery sections exposed on the glass cell predetermined regions to form a plurality of reinforced sections; and
removing the linking bridges to separate the glass cell predetermined regions having the reinforced sections so as to form a plurality of reinforced glass cells.

2. The method of fabricating the reinforced glass cell as claimed in claim 1, further comprising routing the periphery section of each of the glass cell predetermined regions before performing the reinforcing process.

3. The method of fabricating the reinforced glass cell as claimed in claim 1, wherein a method of removing a portion of the mother glass on the outer edge of each of the glass cell predetermined regions to form the through trench on the edge of each of the glass cell predetermined regions comprises a physical borehole process, an etching process, or a laser process.

4. The method of fabricating the reinforced glass cell as claimed in claim 1, further comprising forming a patterned protection film on the glass cell predetermined regions and a plurality of predetermined formation regions of the linking bridges before removing a portion of the mother glass from the outer edge of each of the glass cell predetermined regions.

5. The method of fabricating the reinforced glass cell as claimed in claim 1, wherein in a perimeter occupied by each of the glass cell predetermined regions, a length of the through trench is longer than a length of the linking bridge.

6. The method of fabricating the reinforced glass cell as claimed in claim 1, further comprising forming a touch device on each of the glass cell predetermined regions of the patterned mother glass, each of the reinforced glass cells formed being a touch panel after the linking bridges are removed.

7. A reinforced glass cell, comprising:
a glass substrate having an upper surface, a lower surface, and a periphery surrounding side surface, wherein the periphery surrounding side surface connects the upper surface and the lower surface, and has at least one reinforced section and at least one unreinforced section with an area of the reinforced section being larger than an area of the unreinforced section.

8. The reinforced glass cell as claimed in claim 7, wherein the reinforced section and the unreinforced section have an alkali metal ion with an atomic radius larger than an atomic radius of sodium, and a concentration of the alkali metal ion in the reinforced section is higher than a concentration of the alkali ion in the unreinforced section.

9. The reinforced glass cell as claimed in claim 7, wherein a reinforcing depth of the upper surface, the lower surface, and the reinforced section of the glass substrate ranges from greater than 0 μm to 150 μm.

10. The reinforced glass cell as claimed in claim 7, wherein a material of the glass substrate comprises an alkali free glass, a boron glass, an aluminosilicate glass, a lithium aluminum silicate glass, or a soda-lime glass.

11. The reinforced glass cell as claimed in claim 7, wherein the reinforced glass cell is a touch panel or a transparent cover glass.

12. A cover glass, comprising:
a reinforced glass cell having an upper surface, a lower surface, and a periphery surrounding side surface, wherein the periphery surrounding side surface connects the upper surface and the lower surface, and has at least one reinforced section and at least one unreinforced section with an area of the reinforced section being larger than an area of the unreinforced section;
a touch sensing electrode structure, disposed on at least one surface of the reinforced glass cell; and
a decoration layer, disposed on the reinforced glass cell.

13. The cover glass as claimed in claim 12, wherein the decoration layer is disposed on a periphery of the reinforced glass cell.

14. The cover glass as claimed in claim 12, wherein the decoration layer is constituted by at least one of diamond-like carbon, ceramic, ink, or photo-resist material.

15. The cover glass as claimed in claim 12, further comprising:
at least one functional film, disposed on at least one side of the reinforced glass cell and comprising at least one of a polaroid, a filter glass, an anti-glare filter, an anti-reflection film, a polyethylene terephthalate (PET) material, or a hard coating material.

16. The cover glass as claimed in claim 12, further comprising:
a protection layer, wherein the touch sensing electrode structure is disposed between the protection layer and the reinforced glass cell.
